(19) United States
(12) Patent Application Publication
(10) Pub. No.: US 2015/0343495 A1
(43) Pub. Date: Dec. 3, 2015

(54) APPARATUS AND METHODS FOR TREATING SUBSTRATES

(71) Applicants: Kyoungseob KIM, Suwon-si (KR); Yongsun KO, Suwon-si (KR); SeokHoon KIM, Seongnam-si (KR); Kuntack LEE, Suwon-si (KR); Hyosan LEE, Hwaseong-si (KR); Gilheyun CHOI, Seoul (KR)

(72) Inventors: Kyoungseob KIM, Suwon-si (KR); Yongsun KO, Suwon-si (KR); SeokHoon KIM, Seongnam-si (KR); Kuntack LEE, Suwon-si (KR); Hyosan LEE, Hwaseong-si (KR); Gilheyun CHOI, Seoul (KR)

(21) Appl. No.: 14/682,349

(22) Filed: Apr. 9, 2015

(30) Foreign Application Priority Data
Jun. 3, 2014 (KR) 10-2014-0067739

(51) Int. Cl. B08B 3/02; H01L 21/67

(52) U.S. Cl. CPC B08B 3/02; H01L 21/67051

(57) ABSTRACT

An apparatus for treating a substrate includes a spin chuck supporting a substrate, a nozzle movably disposed on the spin chuck, the nozzle providing droplets of a treatment liquid onto a surface of the substrate, and a nozzle arm moving the nozzle above the spin chuck, wherein the nozzle arm moves the nozzle horizontally along the surface of the substrate, and vertically with respect to the surface of the substrate, wherein the nozzle arm moves the nozzle between an edge of the substrate and a center of the substrate, the nozzle moving away from the surface of the substrate while approaching toward the center of the substrate, and wherein droplets provided onto the center of the substrate have a smaller vertical spacing than that of droplets provided onto the edge of the substrate.

### CROSS-REFERENCE TO RELATED APPLICATION

Korean Patent Application No. 10-2014-0067739, filed on Jun. 3, 2014, in the Korean Intellectual Property Office, and entitled: “Apparatus and Methods for Treating Substrates,” is incorporated by reference herein in its entirety.

### BACKGROUND

1. Field

Embodiments relate to apparatus and methods for treating substrates and, more particularly, to apparatus and methods for treating substrates capable of suppressing damages to substrates.

2. Description of the Related Art

In production processes for semiconductor devices and liquid crystal display devices, semiconductor wafers and glass substrates are treated with a treatment liquid. A substrate treatment apparatus of a single substrate treatment type adapted to treat a single substrate generally includes a droplet nozzle which provides droplets of the treatment liquid onto a surface of the substrate held by a spin chuck. In the substrate treatment apparatus, the substrate is cleaned by causing the droplets to impinge the surface of the substrate.

### SUMMARY

Embodiments provide apparatus and methods for treating substrates, which clean the substrates without damages thereto.

Embodiments also provide apparatus and methods for treating substrates capable of controlling injection quantity of treatment liquid per each unit area of the substrate.

Embodiments further provide apparatus and methods for treating substrates, which improve efficiency of the substrate treatment.

Embodiments additionally provide apparatus and methods for treating substrates in which supply imbalance of treatment liquid caused by the difference of linear velocity of the substrate is compensated for by vertically ascending the droplet nozzle away from the substrate or by changing the speed of the droplet nozzle.

According to an exemplary embodiment, an apparatus for treating a substrate may comprise: a spin chuck supporting a substrate; a nozzle that is movably disposed on the spin chuck and provides droplets of a treatment liquid onto a surface of the substrate supported by the spin chuck; and a nozzle arm that drives the nozzle to move on the spin chuck. The nozzle arm may drive the nozzle to horizontally move along the surface of the substrate and drives the nozzle to vertically move respect to the surface of the substrate. The nozzle may move between an edge of the substrate and a center of the substrate by a driving of the nozzle arm. The nozzle may move away from the surface of the substrate while approaching toward the center of the substrate. The droplet provided onto the center of the substrate may have a vertical spacing less than that of the droplets provided onto the edge of the substrate.

In some embodiments, the nozzle may be spaced apart from the edge of the substrate by a first gap and spaced apart from the center of the substrate by a second gap greater than the first gap.

In some embodiments, the nozzle may continuously or stepwisely climb toward the center of the substrate from the edge of the substrate.

In some embodiments, the nozzle may gradually ascend away from the substrate while moving toward the center of the substrate from a side edge of the substrate and may gradually descend toward the substrate while returning toward the side edge of the substrate from the center of the substrate. The side edge of the substrate may intersect a traveling path of the nozzle.

In some embodiments, the nozzle may gradually ascend away from the substrate while moving toward the center of the substrate from one of opposing lateral edges of the substrate and may gradually descend toward the substrate while returning toward the other of opposing lateral edges of the substrate from the center of the substrate. The opposing lateral edges of the substrate may intersect a traveling path of the nozzle.

In some embodiments, the nozzle may be spaced apart from the edge of the substrate by a first gap and spaced apart from the center of the substrate by a second gap greater than the first gap. A ratio of the first gap to the second gap may be about 1:2.

In some embodiments, the substrate may include a boundary that divides a radius thereof. The nozzle may move along a horizontal path that passes across an outer region between the edge and the boundary of the substrate and along an ascending path that passes across an inner region between the boundary and the center of the substrate. The horizontal path may have substantially no variation of gap between the nozzle and the surface of the substrate. The ascending path may gradually move away from the surface of the substrate while approaching the center of the substrate.

In some embodiments, the nozzle may reciprocate between the edge and the center of the substrate at least one time. The nozzle may horizontally move between the edge and the boundary of the substrate without a variation of gap between the nozzle and the surface of the substrate. The nozzle may move from the boundary of the substrate to the center of the substrate while gradually ascending away from the surface of the substrate while approaching the center of the substrate. The nozzle may move from the center of the substrate to the boundary of the substrate while gradually descending toward the surface of the substrate while approaching the boundary of the substrate.

In some embodiments, the nozzle may reciprocate between opposing lateral edges of the substrate across the center of the substrate at least one time. The opposing lateral edges of the substrate may intersect a traveling path of the nozzle. The nozzle may horizontally move between each of the opposing lateral edges and the boundary of the substrate without a variation of gap between the nozzle and the surface of the substrate. The nozzle may move from the boundary of the substrate to the center of the substrate while gradually ascending away from the surface of the substrate while approaching the center of the substrate. The nozzle may move from the center of the substrate to the boundary of the substrate while gradually descending toward the surface of the substrate while approaching the boundary of the substrate.

In some embodiments, the nozzle may be respectively spaced apart from the edge and boundary of the substrate by a first gap. The nozzle may be spaced apart from the center of the substrate by a second gap greater than the first gap. A ratio of the first gap to the second gap may be about 1:2.

According to another exemplary embodiment, an apparatus for treating a substrate may comprise: a spin chuck holding a substrate; a nozzle that is movably disposed on the spin chuck and provides droplets of a treatment liquid onto a surface of the substrate held by the spin chuck; and a nozzle arm that drives the nozzle to horizontally move along the surface of the substrate rotating around a center thereof on the spin chuck and drives the nozzle to vertically move with respect to the surface of the substrate. The nozzle arm may drive the nozzle to move along the surface of the substrate with a variation of gap between the nozzle and the surface of the substrate. The droplets provided onto the center of the substrate may have a vertical spacing less than that of the droplets provided onto the edge of the substrate.

In some embodiments, a second gap between the center of the substrate and the nozzle may be greater than a first gap between the edge of the substrate and the nozzle. A ratio of the first gap to the second gap may be about 1:2.

In some embodiments, the nozzle arm may drive the nozzle to move along an ascending path gradually getting away from the substrate while approaching toward the center of the substrate from the edge of the substrate.

In some embodiments, the nozzle may be spaced apart from the edge of the substrate by the first gap. The nozzle may be spaced apart from the center of the substrate by the second gap. The nozzle may be spaced apart from the surface between the edge and the center of the substrate by a third gap having a range of from the first gap to the second gap. The third gap may gradually increase while approaching toward the center of the substrate from the edge of the substrate.

In some embodiments, the nozzle arm may drive the nozzle to move toward the center of the substrate from the edge of the substrate in a hybrid mode. The hybrid mode may includes: a horizontal movement along a horizontal path having substantially no variation of gap between the nozzle and the substrate in an area from the edge of the substrate to an intermediate between the edge and the center of the substrate; and a vertical movement along an ascending path gradually getting away from the substrate in an area from the intermediate point of the substrate to the center of the substrate.

In some embodiments, the nozzle may be spaced apart from the substrate between the edge and the intermediate of the substrate by the first gap. The nozzle may be spaced apart from the center of the substrate by the second gap. The nozzle may be spaced apart from the surface between the intermediate and the center of the substrate by a third gap having a range of from the first gap to the second gap. The third gap may gradually increase while approaching toward the center of the substrate from the intermediate of the substrate.

In some embodiments, the nozzle arm may drive the nozzle to move along a locus on the surface of the substrate. The locus may extend between the edge and the center of the substrate.

In some embodiments, the nozzle arm may drive the nozzle to move along a locus on the surface of the substrate. The locus may extend across an entire surface of the substrate and passing through the center of the substrate.

In some embodiments, the apparatus may further comprise a second nozzle that is movably disposed around the nozzle and provides a second treatment liquid onto the surface of the substrate on which the droplets are provided from the nozzle.

According to yet another exemplary embodiment, an apparatus for treating a substrate may comprise: a nozzle arm that drives a nozzle to move along a surface of a substrate held by a spin chuck and changes a gap between the nozzle and the surface of the substrate. The nozzle may provide droplets of a treatment liquid onto the surface of the substrate which is rotating on the spin chuck. The droplets provided onto a center of the substrate may have a first vertical spacing different from a second vertical spacing of the droplets provided onto the edge of the substrate.

In some embodiments, the nozzle may be spaced apart from the edge of the substrate by a first gap and spaced apart from the center of the substrate by a second gap greater than the first gap and within twice the first gap. The second vertical spacing of the droplets provided from the nozzle spaced apart from the center of the substrate by the second gap may be less than the first vertical spacing of the droplets provided from the nozzle spaced apart from the edge of the substrate by the first gap.

In some embodiments, a ratio of the first gap to the second gap may be about 1:2.

In some embodiments, the nozzle arm may drive the nozzle to continuously ascend while approaching toward the center of the substrate from the edge of the substrate. The nozzle may be spaced apart from the surface between the edge and the center of the substrate by a third gap having a range of from the first gap to the second gap. The third gap may gradually increase while approaching toward the center of the substrate.

In some embodiments, the nozzle arm may drive the nozzle to move along a direction toward the center of the substrate from the edge of the substrate such that the nozzle may move across an outer region of the substrate adjacent to the edge of the substrate and an inner region of the substrate adjacent to the center of the substrate. The nozzle may be spaced apart from the surface of the substrate by the first gap in the outer region of the substrate. The nozzle may be spaced apart from the surface of the substrate by a third gap between the first and second gaps in the inner region of the substrate. The third gap may gradually increase while approaching toward the center of the substrate.

In some embodiments, the nozzle may move along a locus extending from the edge of the substrate to the center of the substrate at a distant from the surface of the substrate. The locus may include a curved or straight line. A gap between the nozzle and the surface of the substrate may be changeable.

In some embodiments, the nozzle may move along a locus extending between opposing lateral edges of the substrate and passing through the center of the substrate at a distant form the surface of the substrate. The locus may include a curved or straight line. A gap between the nozzle and the surface of the substrate may be changeable.

In some embodiments, the droplets having the first vertical spacing may be injected through the nozzle spaced apart from the edge of the substrate by the first gap. The droplets having the second vertical spacing may be injected through the nozzle spaced apart from the center of the substrate by the second gap. A ratio of the first gap to the second gap may be about 1:2. The nozzle may spray the droplet whose an injection quantity per unit time is substantially constant.

In some embodiments, the nozzle may be spaced apart from the edge of the substrate by a first gap and spaced apart from the center of the substrate by a second gap less than the first gap. The second vertical spacing of the droplets provided from the nozzle spaced apart from the center of the substrate by the second gap may be greater than the first vertical spacing of the droplets provided from the nozzle spaced apart from the edge of the substrate by the first gap. A ratio of the second gap to the first gap may be about 1:2.

According to still another exemplary embodiment, a method for treating a substrate may comprise: providing droplets of a cleaning liquid from a nozzle onto a substrate so as to clean the substrate. The cleaning of the substrate may include: rotating the substrate; providing the droplets onto a surface of the substrate while moving the nozzle toward a center of the substrate from one edge of the substrate; and moving the nozzle away from the surface of the substrate while approaching toward the center of the substrate. A vertical spacing of the droplets provided onto the center of the substrate may be less than a vertical spacing of the droplets provided onto the one edge of the substrate.

In some embodiments, the moving of the nozzle away from the surface of the substrate may includes gradually ascending the nozzle away from the surface of the substrate while moving the nozzle toward the center of the substrate from the one edge of the substrate.

In some embodiments, the nozzle may be spaced apart from a surface of the substrate corresponding to the one edge of the substrate by a first gap. The nozzle may be spaced apart from a surface of the substrate corresponding to the center of the substrate by a second gap two times greater than the first gap. The nozzle may be spaced apart from a surface of the substrate corresponding to area between the one edge and the center of the substrate by a third gap having a range of from the first gap to the second gap. The third gap may gradually increase while approaching toward the center of the substrate from the one edge of the substrate.

In some embodiments, the moving of the nozzle away from the surface of the substrate may include: horizontally moving the nozzle from the one edge of the substrate to an intermediate between the one edge and the center of the substrate without a variation of gap between the nozzle and the substrate; and ascending the nozzle away from the substrate while moving the nozzle from the intermediate of the substrate to the center of the substrate.

In some embodiments, the nozzle may be spaced apart from a surface of the substrate corresponding to the one edge and the intermediate of the substrate by a first gap. The nozzle may be spaced apart from a surface of the substrate corresponding to the center of the substrate by a second gap two times greater than the first gap. The nozzle may be space apart from a surface of the substrate corresponding to an area between the intermediate and the center of the substrate by a third gap having a range of from the first gap to the second gap. The third gap may gradually increase while approaching toward the center of the substrate from the intermediate of the substrate.

In some embodiments, after the moving of the nozzle away from the surface of the substrate, the cleaning of the substrate may further include moving the nozzle toward the surface of the substrate while moving the nozzle from the center of the substrate toward an opposing edge of the substrate opposite the one edge of the substrate.

In some embodiments, the moving of the nozzle toward the surface of the substrate may comprise gradually descending the nozzle toward the surface of the substrate while moving the nozzle from the center of the substrate toward the opposing edge of the substrate.

In some embodiments, the nozzle may be spaced apart from a surface of the substrate corresponding to the opposing edge of the substrate by a first gap. The nozzle may be spaced apart from a surface of the substrate corresponding to the center of the substrate by a second gap two times greater than the first gap. The nozzle may be spaced apart from a surface of the substrate corresponding to an area between the opposing edge and the center of the substrate by a third gap having a range of from the first gap to the second gap. The third gap may gradually decrease while approaching toward the opposing edge of the substrate from the center of the substrate.

In some embodiments, the moving of the nozzle toward the surface of the substrate may comprise: gradually descending the nozzle toward the surface of the substrate while moving the nozzle from the center of the substrate toward an intermediate of the substrate between the center and the opposing edge of the substrate; and horizontally moving the nozzle from the intermediate of the substrate to the opposing edge of the substrate without a variation of gap between the nozzle and the substrate.

In some embodiments, the nozzle may be spaced apart from a surface of the substrate corresponding to the intermediate of the substrate by a first gap. The nozzle may be spaced apart from a surface of the substrate corresponding to the center of the substrate by a second gap two times greater than the first gap. The nozzle may be spaced apart from a surface of the substrate corresponding to an area between the intermediate and the center of the substrate by a third gap having a range of from the first gap to the second gap. The third gap may gradually decrease while approaching toward the intermediate of the substrate from the center of the substrate.

In some embodiments, the cleaning of the substrate may further include providing a wetting liquid from a second nozzle onto the surface of the substrate on which the droplets are provided.

According to yet another exemplary embodiment, a method for treating a substrate may comprise: rotating a substrate around a center thereof; providing droplets of a cleaning liquid onto a surface of the rotating substrate from a nozzle moving toward the center of the substrate from an edge of the substrate; arranging the nozzle to be spaced apart from a surface of the substrate corresponding to the edge of the substrate by a first gap; and arranging the nozzle to be spaced apart from a surface of the substrate corresponding to the center of the substrate by a second gap greater than the first gap. A vertical spacing of the droplets provided onto the center of the substrate may be less than a vertical spacing of the droplets provided onto the edge of the substrate.

In some embodiments, a ratio of the first gap to the second gap may be about 1:2.

In some embodiments, after arranging the nozzle to be spaced apart from a surface of the substrate corresponding to the edge of the substrate by a first gap, the method may further comprise continuously ascending the nozzle away from the surface of the substrate until the nozzle approaches the center of the substrate. The nozzle may be spaced apart from an area between the edge and the center of the substrate by a third gap having a range of from the first gap to the second gap. The third gap may gradually increase while approaching toward the center of the substrate.

In some embodiments, after arranging the nozzle to be spaced apart from a surface of the substrate corresponding to the edge of the substrate by a first gap, the method may further comprise: arranging the nozzle to be spaced apart from the surface of the substrate by the first gap until the nozzle approaches an intermediate of the substrate between the edge and the center of the substrate; and thereafter, continuously ascending the nozzle away from the surface of the substrate until the nozzle approaches the center of the substrate. The nozzle may be spaced apart from a surface of the substrate between the intermediate and the center of the substrate by a third gap having a range of from the first gap to the second gap. The third gap may gradually increase while approaching toward the center of the substrate.

According to still another exemplary embodiment, an apparatus for treating a substrate includes a spin chuck supporting a substrate, a movable nozzle above the spin chuck, the nozzle providing droplets of a treatment liquid onto a surface of the substrate, and a nozzle arm attached to the nozzle and moving the nozzle between an edge of the substrate and a center of the substrate, droplets of the treatment liquid provided onto the center of the substrate having a smaller vertical spacing than that of droplets provided onto the edge of the substrate.

In some embodiments, the nozzle arm may move the nozzle between the edge of the substrate and the center of the substrate along the surface of the substrate, while varying a vertical distance between the nozzle and the surface of the substrate.

In some embodiments, the vertical distance between the nozzle and the surface of the substrate may increase as a horizontal distance between the nozzle and the center of the substrate decreases.

In some embodiments, a ratio between a minimum vertical distance and a maximum vertical distance may be about 1:2.

The minimum vertical distance may be at the edge of the substrate, and the maximum vertical distance may be at the center of the substrate.

### BRIEF DESCRIPTION OF THE DRAWINGS

Features will become apparent to those of ordinary skill in the art by describing in detail exemplary embodiments with reference to the attached drawings, in which:

FIG. 1A illustrates a schematic view of an apparatus for treating a substrate according to an exemplary embodiment;

FIG. 1B illustrates a schematic diagram of a portion of FIG. 1A;

FIG. 1C illustrates a plan view of a portion of FIG. 1A;

FIG. 2A is a table illustrating spray appearances of droplets according to flow rates;

FIG. 2B is a graph illustrating frequency according to jetting velocity capable of acquiring stable droplet injection;

FIG. 2C is a table illustrating spray appearances of droplets according to gaps between nozzles and substrates;

FIGS. 3A to 3E illustrate cross-sectional views of stages in a method for treating a substrate using the apparatus of FIG. 1A;

FIG. 4A illustrates a plan view of an apparatus for treating a substrate according to another exemplary embodiment;

FIG. 4B illustrates a plan view of a portion of FIG. 4A;

FIG. 4C illustrates a plan view of a modified example of FIG. 4B; and

FIGS. 5A to 5E illustrate cross-sectional views of stages in a method for treating a substrate using an apparatus of FIG. 4A.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

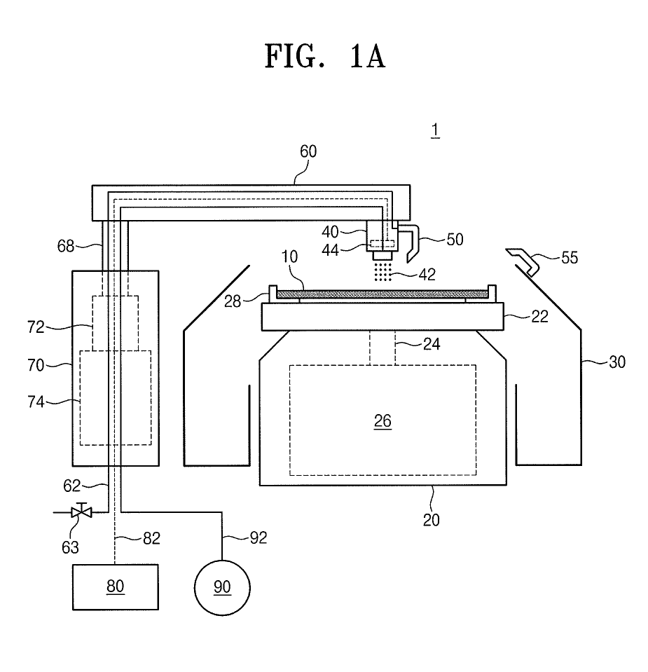

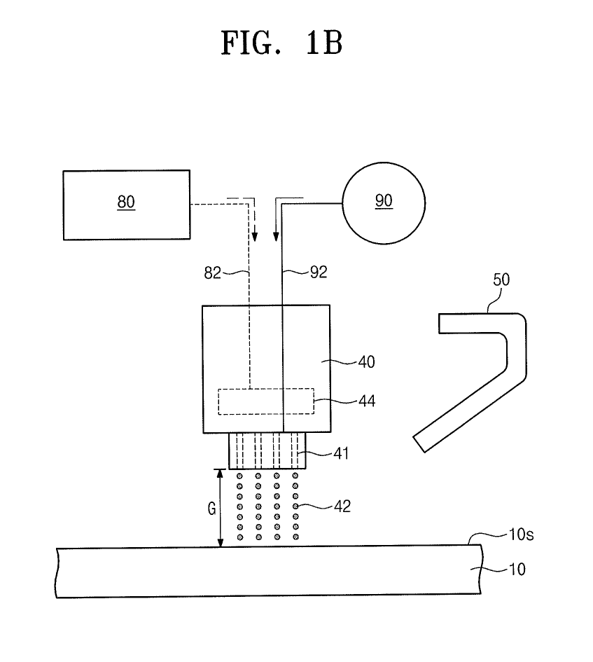

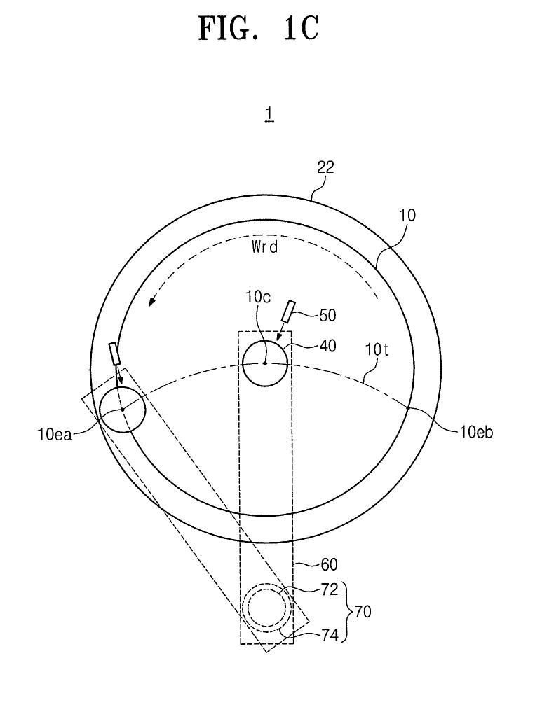

FIG. 1A illustrates a schematic view of an apparatus for treating a substrate according to an exemplary embodiment. FIG. 1B illustrates a schematic diagram of a portion of FIG. 1A. FIG. 1C illustrates a plan view of a portion of FIG. 1A.

Referring to FIGS. 1A and 1B, a substrate treatment apparatus 1 may be a substrate cleaning apparatus of a single-wafer treatment type that cleans substrates, such as semiconductor wafers or glass substrates, one by one. The substrate treatment apparatus 1 may remove particles from a surface 10s of a substrate 10 by pressure or physical impacts applied thereto by droplets 42 of a cleaning liquid provided onto the substrate 10. The substrate treatment apparatus 1 may include a spin unit 20 that horizontally holds and rotates the substrate 10, a bowl 30 that surrounds the spin unit 20, a droplet nozzle 40 that provides the droplets 42 of the cleaning liquid onto the substrate 10, a nozzle arm 60 that moves the droplet nozzle 40 on, e.g., above, the substrate 10 by a driving force of a driving unit 70, a side nozzle 50 that provides a wetting liquid onto the substrate 10, and a rinse nozzle 55 that provides a rinsing liquid on the substrate 10.

The substrate treatment apparatus 1 may further include a pump 90 that provides the droplet nozzle 40 with the cleaning liquid after pressurizing the cleaning liquid, a generator 80 that creates the droplets 42 after applying frequency to the cleaning liquid, and a valve 63 that controls the flow of the wetting liquid.

The spin unit 20 may include a spin chuck 22 on which the substrate 10 is horizontally held, a spin motor 26 that rotates the spin chuck 22, and a rotating axis 24 that is connected to a center of the spin chuck 22 to convey the driving force of the motor 26 to the spin chuck 22. The substrate 10 may rotate around a central axis of the spin chuck 22. The spin chuck 22 may be a clamp chuck having at least one clamp 28 adapted to grip the substrate 10. Alternatively, the spin chuck 22 may be a vacuum chuck that holds the substrate 10 by suction of the substrate 10.

The bowl 30 may receive treatment liquids, e.g., a cleaning liquid, a wetting liquid, and a rinsing liquid, scattered by a centrifugal force from the substrate 10 which is rotating on the spin chuck 22. The treatments liquids received in the bowl 30 may be drained from the substrate treatment apparatus 1. The bowl 30 may be shaped like a cup or a cylinder having a diameter greater than that of the substrate 10 and a top portion extending upwardly toward the substrate 10.

The droplet nozzle 40 may be an inkjet nozzle that sprays the droplets 42, as illustrated in FIG. 1B. The droplet nozzle 40 may include a piezoelectric device 44 provided therein. The piezoelectric device 44 may be electrically connected to a generator 80 through an electrical line 82, such that an AC voltage may be applied to the piezoelectric device 44. The treatment liquid may be pressurized by a pump 90 and provided into the droplet nozzle 40 through a liquid supply line 92. The cleaning liquid provided into the droplet nozzle 40 may be changed into the droplets 42 by the piezoelectric device 44 which is vibrating at a frequency corresponding to a frequency of the AC voltage supplied from the generator 80, and the droplet nozzle 40 may spout out the droplets 42 onto the substrate 10. The cleaning liquid may include, e.g., electrolytic ionized water, de-ionized water (DIW), carbonated water, SCl water (NH₄OH+H₂O₂+DIW), an alkaline-based chemical, an acid-based chemical, and an organic-based chemical. For example, the droplet nozzle 40 may be installed at a bottom end of the nozzle arm 60. In another example, the droplet nozzle 40 may be settled at a side end of the nozzle arm 60.

The nozzle arm 60 may be arranged to move the droplet nozzle 40. For example, the nozzle arm 60 may be connected to the driving unit 70 through a pivot axis 68. The driving unit 70 may include a rotating mechanism 72, e.g., a step motor that horizontally pivots the nozzle arm 60, and a lifting mechanism 74, e.g., a cylinder that vertically moves the nozzle arm 60. The horizontal and vertical movement of the nozzle arm 60 may horizontally and vertically move the droplet nozzle 40. The electrical line 82 and the supply line 92 may be installed inside of the nozzle arm 60.

The side nozzle 50 may be provided at a side of the droplet nozzle 40 to obliquely discharge the wetting liquid onto the substrate 10, such that a wetting liquid layer may be formed on the surface 10s of the substrate 10. Alternatively, the side nozzle 50 may be provided at a side or a bottom of the nozzle arm 60. The wetting liquid may be provided to the side nozzle 50 through a wetting liquid supplying line 62. The wetting liquid supplying line 62 may be equipped in the nozzle arm 60. For example, the wetting liquid may include the cleaning liquid described above and/or a rinsing liquid, e.g., hydrogen water, ozone water, diluted hydrochloric acid aqueous solution, or isopropyl alcohol. The rinsing liquid may be provided onto the surface 10s of the substrate 10 together with the cleaning liquid.

The rinse nozzle 55 may provide the rinsing liquid onto the substrate 10. For example, the rinsing liquid may include at least one of de-ionized water (DIW), carbonated water, electrolytically ionized water, hydrogen water, ozone water, and diluted hydrochloric acid aqueous solution. The rinsing liquid may be provided onto the surface 10s of the substrate 10 before and/or after the substrate cleaning treatment. The rinse nozzle 55 may be fixedly installed outside the bowl 30.

Referring to FIG. 1C, the rotating mechanism 72 may pivotally rotate the nozzle arm 60. For example, the pivotal rotation of the nozzle arm 60 may horizontally move the droplet nozzle 40 along a locus 10t on the substrate 10 held by the spin chuck 22. The locus 10t may be an arcuate curve which extends between a left edge position 10ea and a right edge position 10eb of the substrate 10 and passes through a central position 10c of the substrate 10. In another example, the nozzle arm 60 may horizontally move the droplet nozzle 40 along a straight line passing through the central position 10c of the substrate 10. The lifting mechanism 74 may raise or lower the nozzle arm 60 in a state the droplet nozzle 40 is placed over the substrate 10, such that the droplet nozzle 40 may move close to or away from the surface 10s of the substrate 10.

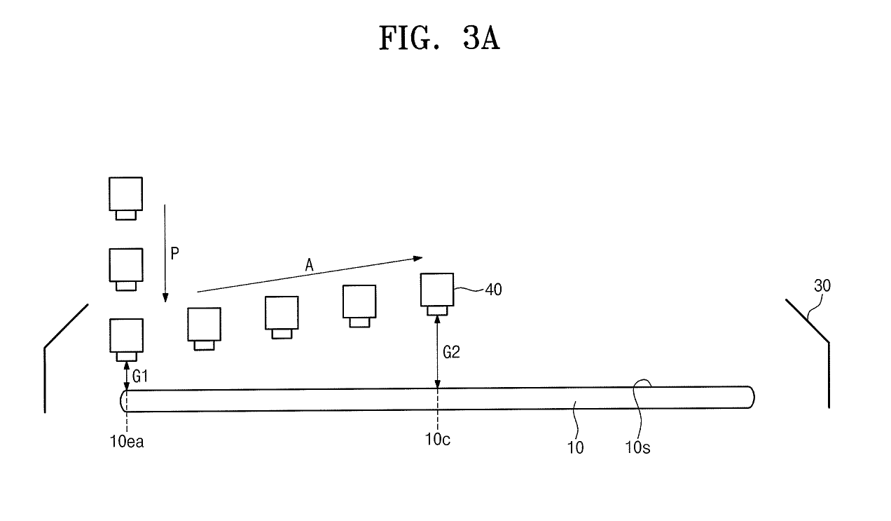

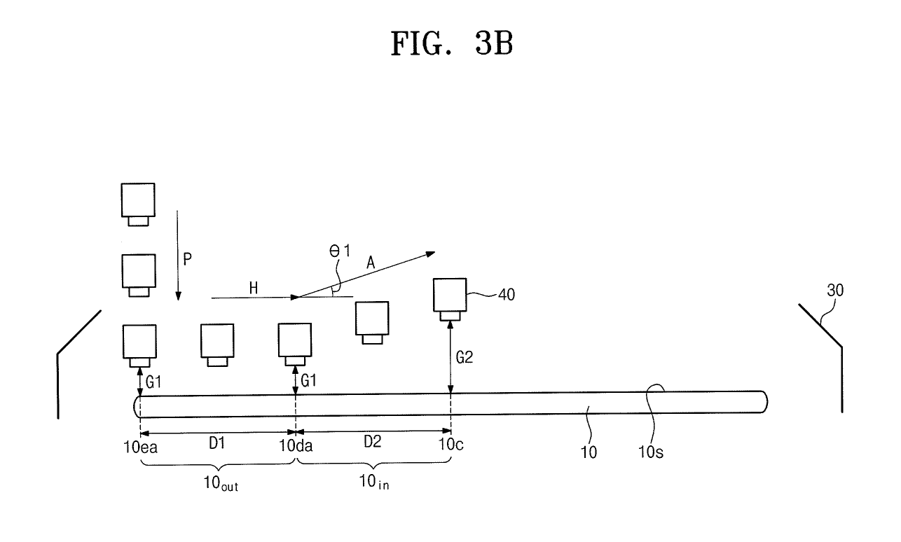

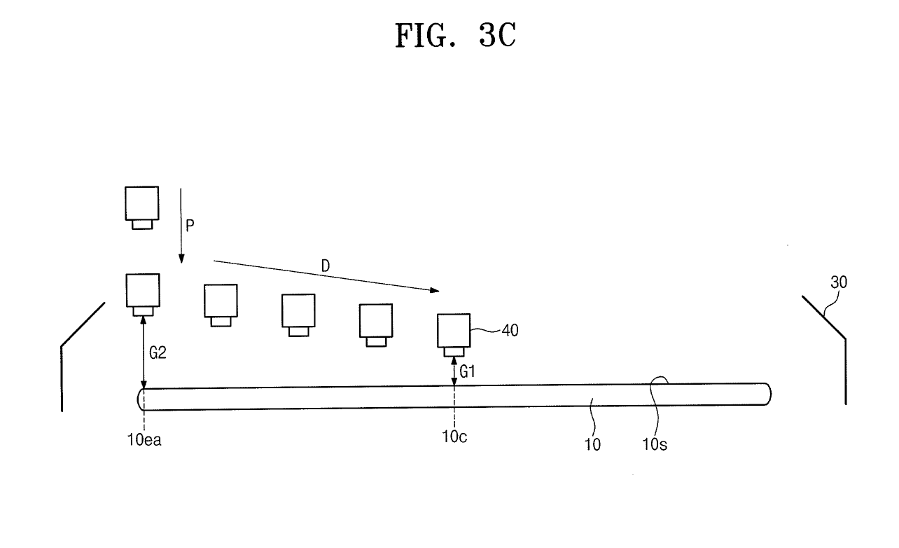

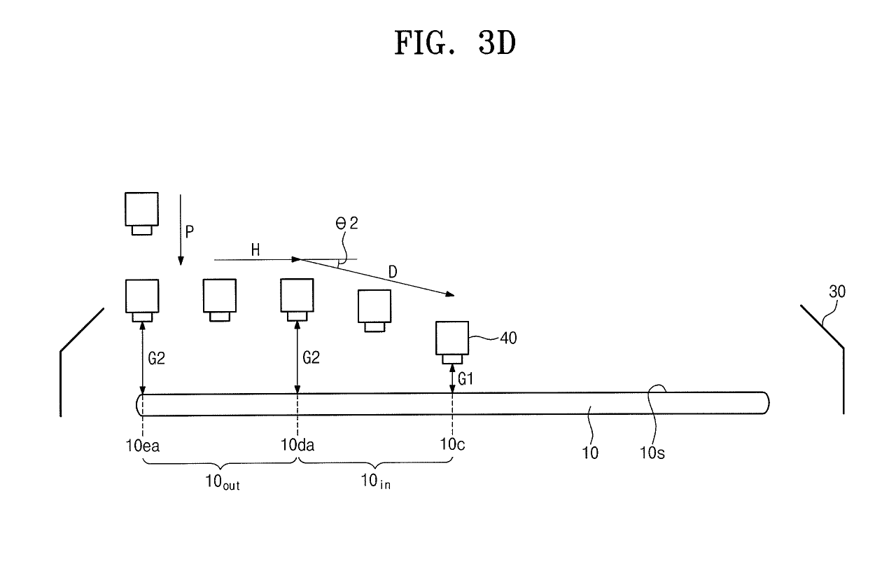

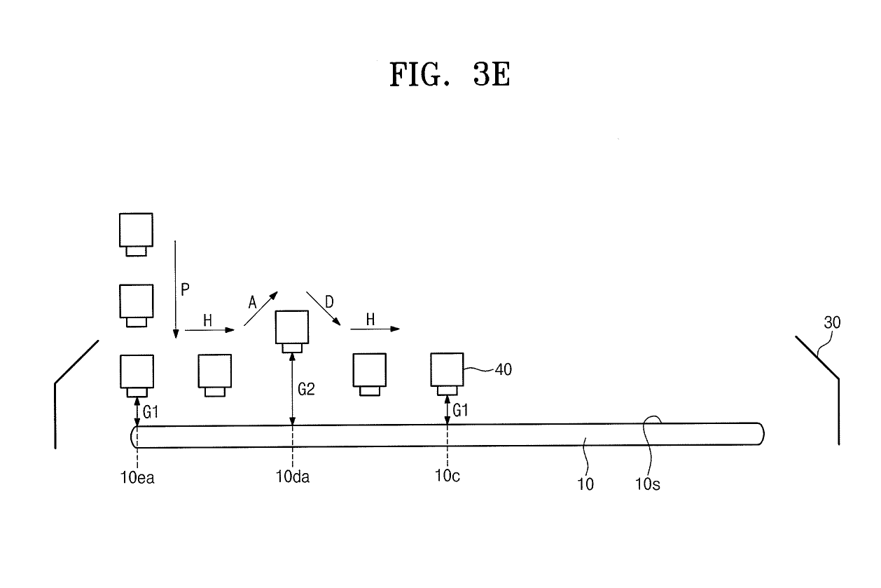

For example, the droplet nozzle 40 may horizontally move along the locus 10t by the rotating mechanism 72 while spraying the droplets 42 onto the surface 10s of the substrate 10. The horizontal moving speed of the droplet nozzle 40 may be controlled by adjusting an operation speed of the rotating mechanism 72. When the droplet nozzle 40 spays the droplets 42, while horizontally moving along the locus 10t, the lifting mechanism 74 may move the droplet nozzle 40 close to or away from the surface 10s of the substrate 10. As such, by operation of the rotating mechanism 72 and/or the lifting mechanism 74, the droplet nozzle 40 may spray the droplets 42 onto the surface 10s of the substrate 10 while horizontal moving along the locus 10t without or with vertical movement. This will be described later in detail with reference to FIGS. 3A to 3E.

The side nozzle 50 may spray the wetting liquid onto the surface 10s of the substrate 10, while moving along the locus 10t by the pivot rotation of the nozzle arm 60. A position of the side nozzle 50 may be adjusted to inject the wetting liquid in a direction consistent with a rotation direction Wrd of the substrate 10. If the rotation direction Wrd of the substrate 10 is leftward, the side nozzle 50 may be positioned to inject the wetting liquid in a direction (designated by a solid arrow) toward the droplet nozzle 40. For example, the side nozzle 50 may be positioned at an upstream side of the rotation direction Wrd and the droplet nozzle 40 may be placed at a downstream side of the rotation direction Wrd.

The side nozzle 50 may move together with the droplet nozzle 40. Therefore, the horizontal moving path of the droplet nozzle 40 may coincide with an injecting direction of the wetting liquid from the side nozzle 50 and with the rotation direction Wrd of the substrate 10. For example, the nozzle arm 60 may be pivotally rotated to reciprocate, e.g., move, the droplet nozzle 40 along the locus 10t between the left edge position 10ea and the central position 10c of the substrate 10 while the droplet nozzle 40 is spraying the droplets 42. In other words, the substrate treatment apparatus 1 may have a structure optimized for cleaning the substrate 10 in a half-scan mode.

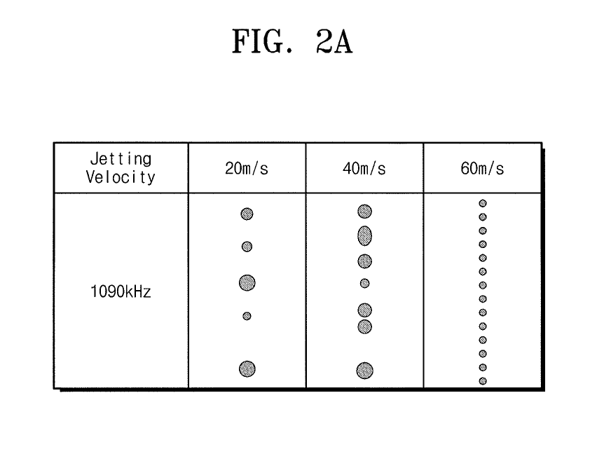

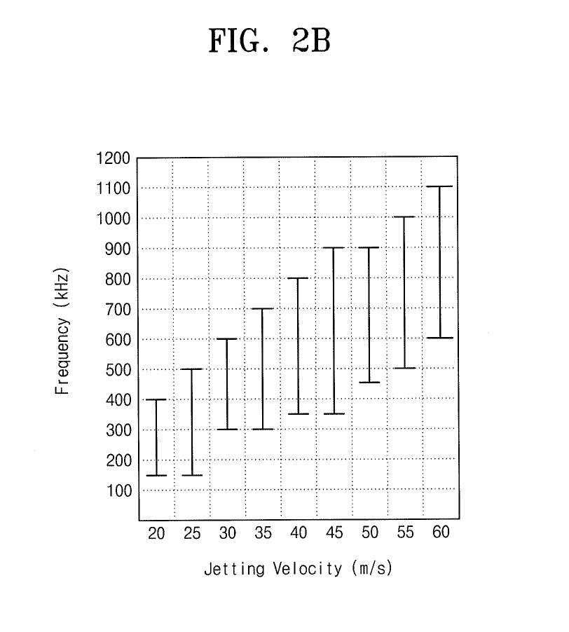

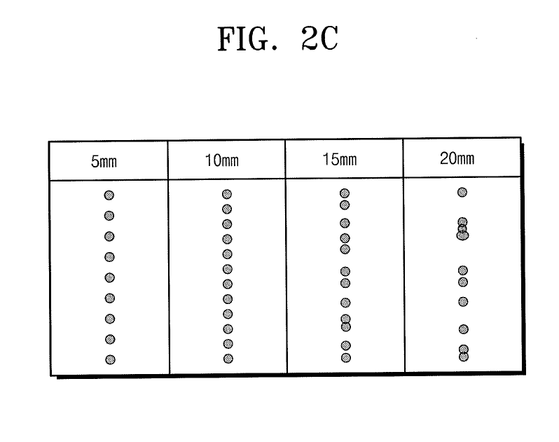

FIG. 2A is a table illustrating spray appearances of droplets according to flow rates. FIG. 2B is a graph illustrating frequency according to jetting velocity capable of acquiring stable droplet injection. FIG. 2C is a table illustrating spray appearances of droplets according to gaps between nozzles and substrates.

As shown in FIG. 1B, the cleaning liquid (designated by a solid arrow directed from the pump 90) may be pressurized by the pump 90 and provided into the droplet nozzle 40. The generator 80 may apply power (designated by a dashed arrow) to the piezoelectric device 44 by which the cleaning liquid is changed into the droplets 42. The droplets 42 may pass through jetting holes 41 and be provided onto the surface 10s of the substrate 10. Assuming that the droplet 42 has a spherical shape, and that the jetting hole 41 has a circular cross section, a size (diameter) and distribution of the droplets 42 may depend on frequency or wavelength of power applied to the piezoelectric device 44, a size (diameter) of the jetting hole 41, and/or a jetting velocity of the droplet 42. The jetting velocity of the droplet 42 may get faster as the pressure of the pump 90 becomes greater. The jetting velocity of the droplet 42 may correspond to a flow rate of the droplet 42.

For example, following Equations 1 and 2 may be used to determine the size of the droplet 42 and a spacing between adjacent droplets 42.

S={(3/2)×d²λ}^{1/3}{(3/2)×d²×(v/f)}^{1/3} (Eq. 1)

λ=v/f=(2/3)×S³×(1/d²) (Eq. 2)

In Equations 1 and 2 above, S denotes the size (diameter) of the droplet 42, d designates the size (diameter) of the jetting hole 41, λ expresses the wavelength, v shows the jetting velocity, and f represents the frequency. The wavelength λ also refers to a spacing between adjacent droplets 42. The spacing between adjacent droplets 42 refers to a vertical gap, i.e., distance, between two sequentially released droplets 42 from a same jetting hole 41 that are vertically provided onto the surface 10s of the substrate 10.

According to Equations 1 and 2 above, the size (diameter) and spacing of the droplet 42 may become smaller as the frequency is increased or the jetting velocity is decreased. The size (diameter) of the droplet 42 may increases, as the size (diameter) of the jetting hole 41 increases.

While the jetting velocity of the droplets 42 is increased to a desired value by the pressure of the pump 90, the size and spacing of the droplets 42 may become non-uniform due to a mismatching between the jetting velocity and the frequency. For example, as shown in FIG. 2A, assuming that a specific value of the frequency (e.g., 1090 kHz) is applied, the size and spacing of the droplet 42 may be non-uniform when the jetting velocity is about 20 m/s and/or about 40 m/s, while the size and spacing of the droplet 42 may be uniform when the jetting velocity is about 60 m/s. In other words, in order to obtain uniform size and spacing of the droplets 42, it may be preferable to apply low frequency when the jetting velocity is slow, and high frequency when the jetting velocity is fast.

FIG. 2B shows a range of frequency to obtain a stable injection of droplet 42 for each jetting velocity. Referring to FIG. 2B, in order to achieve a uniform size (e.g., a diameter of about 13.23 μm) and a uniform spacing (e.g., about 55 μm) of the droplet 42 passing through the jetting hole 41 having a diameter of about 12 μm, it may be preferable to apply a frequency of about 150 kHz to about 400 kHz when the jetting velocity is about 20 m/s, and to apply a frequency of about 600 kHz to about 1100 kHz when the jetting velocity is about 60 m/s. As shown in FIG. 2B, it may be preferable to apply a high frequency in order to obtain a stably fast injection of the droplet 42 and apply a low frequency in order to obtain a stably slow injection of the droplet 42. In case the jetting hole 41 has a diameter of about 8 μm, a range of frequency capable of obtaining a stable injection of the droplet 42 may be identical or similar to that illustrated in FIG. 2B.

Referring to FIG. 1B again, an injection stability and a dropping velocity of the droplet 42 may depend on a gap G between the droplet nozzle 40 and the substrate 10. Referring to FIG. 2C, in case that the droplets 42 are provided onto the surface 10s of the substrate 10 under the condition of adequate jetting velocity and frequency, as formerly described with reference to FIG. 2B, an unstable injection of the droplet 42 may be obtained when the gap G exceeds about 10 mm.

For example, a stable injection of the droplet 42 may be obtained when the gap G is in a range of about 5 mm to about 10 mm under a condition that the jetting velocity and the frequency of FIG. 2B are given. As seen in FIG. 2C, an unstable injection of the droplet 42 occurs when the gap G is larger than 10 mm. In case that the gap G is larger than 10 mm, the dropping velocity of the droplet 42 may be reduced (e.g., a decrease of about 20%) due to air resistance. The decrease of the dropping velocity of the droplet 42 may induce a reduction of kinetic energy (or impact energy) of the droplet 42, such that damages to patterns on the substrate 10 may be diminished. Moreover, the air resistance may reduce the spacing between adjacent droplets 42. In some embodiments, the droplets 42 may be provided onto the surface 10s of the substrate 10 under a condition that the gap G is set to be about 3 mm to about 10 mm.

FIGS. 3A to 3E illustrate cross-sectional views of stages in a method for treating the substrate 10 with the substrate treatment apparatus 1 of FIG. 1A.

For example, referring to FIG. 3A, the surface 10s of the substrate 10 rotating about the central position 10c thereof may receive the droplets 42 (in FIG. 1B) from the droplet nozzle 40, while the droplet nozzle 40 gradually moves, e.g., vertically, away from the surface 10s of the substrate 10. An injection quantity per unit time of the droplets 42 provided from the droplet nozzle 40 may be substantially constant, which may be the same in all of the embodiments disclosed herein.

In another example, the surface 10s of the substrate 10 may receive the droplets 42 from the droplet nozzle 40, while the droplet nozzle 40 moves between the left edge position 10ea and the central position 10c of the substrate 10 at the same or similar speed without changing a gap, i.e., vertical distance, between the droplet nozzle 40 and the substrate 10. In this case, an injection quantity per unit area of the droplets 42 provided on the central position 10c or a central area adjacent thereto may be greater than an injection quantity per unit area of the droplets 42 provided on the left edge position 10ea or an edge area adjacent thereto. In other words, the substrate 10 may rotate around the central position 10c thereof, such that the central position 10c or the central area adjacent thereto may have a smaller linear velocity than the left edge position 10ea or the edge area adjacent thereto. Since the injection quantity per unit time of the droplets 42 leaving the droplet nozzle 40 is substantially constant, the amount of the droplets 42 contacting the central position 10c or the central area adjacent thereto may be greater than that of the droplets 42 contacting the left edge position 10ea or the edge area adjacent thereto. As a result, a relatively large amount of the droplets 42 may damage or impact patterns formed on the central position 10c or the central area adjacent thereto of the substrate 10.

In some embodiments, the droplet nozzle 40 may gradually rise, i.e., vertically move away from the substrate 10, while moving toward the central position 10c from the left edge position 10ea of the substrate 10. As such, pattern damages, resulting from the supply imbalance of the droplets 42 caused by the difference in the linear velocity, may be eliminated or substantially reduced.

For example, referring to FIG. 3A, the droplet nozzle 40 may move along an ascending path A gradually moving away from the surface 10s of the substrate 10, while approaching the central position 10c from the left edge position 10ea of the substrate 10 by simultaneously driving the rotating mechanism 72 and the lifting mechanism 74 of FIG. 1A. The droplet nozzle 40 may horizontally move along the ascending path A at an accelerated, decelerated or constant speed by adjusting the operation speed of the rotating mechanism 72. Similarly, the droplet nozzle may vertically move along the ascending path A at an accelerated, decelerated or constant speed by adjusting the operation speed of the lifting mechanism 74. Horizontal and/or vertical component of the moving speed of the droplet nozzle 40 may be continuously or stepwisely accelerated or decelerated. For example, the horizontal and/or vertical component of the moving speed of the droplet nozzle 40 may be about 200 mm/s or less. The moving speed of the droplet nozzle 40 may also be applicable to other embodiments disclosed hereinafter.

The ascending path A may be linear or non-linear. For example, the ascending path A may be a straight shape, a curved shape protruding convexly from or concavely toward the substrate 10, or a stepwise shape.

The droplet nozzle 40 may gradually rise, while moving toward the central position 10c from the left edge position 10ea of the substrate 10. Therefore, the droplet nozzle 40 may be spaced apart from the left edge position 10ea of the substrate 10 by a first gap G1 and spaced apart from the central position 10c of the substrate 10 by a second gap G2 greater than the first gap G1. The second gap G2 may be about 3 mm to about 10 mm. A ratio of the first gap G1 to the second gap G2 may be about 1:2. For example, the first gap G1 may be about 5 mm, and the second gap G2 may be about 10 mm. In another example, the second gap G2 may be greater than the first gap G1 and less than twice the first gap G1. The values of the first and second gaps G1 and G2 may also be applicable to other embodiments disclosed hereinafter.

The droplet nozzle 40 may progressively ascend, while getting near the central position 10c from the left edge position 10ea, such that the dropping velocity of the droplet 42 may be reduced. The decrease of the dropping velocity of the droplet 42 may induce a reduction of kinetic energy (or impact energy) of the droplet 42 provided onto the central position 10c or the central area adjacent thereto. As a result, the lifting of the droplet nozzle 40 may remove or reduce pattern damages resulting from the supply imbalance of the droplet 42 caused by the difference of the linear velocity.

The unstable injection of the droplet 42 may happen because of mismatching between the jetting velocity and the frequency, while the jetting velocity of the droplet 42 is increased to a desired value, as formerly described with reference to FIG. 1B. When placed on the left edge position 10ea of the substrate 10, after moving inward from outside of the bowl 30 by the rotating mechanism 72, the droplet nozzle 40 may pre-dispense the droplets 42 until a stable injection is achieved. For example, the pre-dispense step may be performed while the droplet nozzle 40 is located at a highest position on the left edge position 10ea of the substrate 10, i.e., at a highest point of path P before moving toward the substrate 10. In another example, the pre-dispense step may occur while the droplet nozzle 40 is vertically moving down along the downward path P on the left edge position 10ea. After the pre-dispense step, the droplet nozzle 40 may move toward the central position 10c from the left edge position 10ea of the substrate 10. The description of the pre-dispense step may be omitted in other embodiments disclosed hereinafter for brevity.

The droplet nozzle 40 may reciprocate, e.g., move, between the left edge position 10ea and the central position 10c of the substrate 10 at least one time. For example, the droplet nozzle 40 may move slantingly upward along the ascending path A toward the central position 10c from the left edge position 10ea, and then move slantingly downward along the ascending path A toward the left edge position 10ea from the central position 10c.

Referring to FIG. 3B, the surface 10s of the substrate 10 rotating about the central position 10c thereof may receive the droplets 42 from the droplet nozzle 40 gradually moving away from the surface 10s of the substrate 10 after horizontally moving without the variation of gap between the droplet nozzle 40 and the surface 10s of the substrate 10.

In some embodiments, the droplet nozzle 40 may move in different ways that are changed at a dividing position 10da between the left edge position 10ea and the central position 10c. For example, the droplet nozzle 40 may move along a horizontal path H in an outer region 10out between the left edge position 10ea and the dividing position 10da, and move along the ascending path A in an inner region 10 in between the dividing position 10da and the central position 10c.

The droplet nozzle 40 may be spaced apart from the surface 10s of the substrate 10 by the first gap G1 in the outer region 10out. The droplet nozzle 40 may gradually rise while moving toward the central position 10c from the dividing position 10da in the inner region 10in. Therefore, the droplet nozzle 40 may be spaced apart from the central position 10c by the second gap G2. The droplet nozzle 40 may move along the horizontal path H at a constant or variable speed. The droplet nozzle 40 may also move along the ascending path A at a constant or variable speed.

The droplet nozzle 40 may inject the droplets 42 onto the surface 10s of the substrate 10 while moving along the ascending path A, such that the droplets 42 may have a reduced impact upon the inner region 10in. It therefore may be possible to eliminate or reduce damages to patterns formed in the inner region 10in of the substrate 10.

The diving position 10da may be arbitrarily determined. For example, if there is an increased risk of damages to patterns formed on the inner region 10in, the diving position 10da may be disposed more adjacent, e.g., closely, to the left edge position 10ea than the central position 10c of the substrate 10.

The droplet nozzle 40 may move at an ascending angle θ1 of about 0° to about 90° within the inner region 10in. The ascending angle θ1 may be determined by Equation 3 below.

θ1=tan⁻¹{(G2−G1)/D2} (Eq. 3)

In Equation 3 above, D2 denotes a length of the inner region 10in, and G2-G1 designates a vertical rising length of the droplet nozzle 40. For example, assuming that the substrate 10 is a 300 mm wafer, the first gap G1 is about 5 mm, the second gap G2 is about 10 mm, and the length D2 is about 75 mm, the ascending angle θ1 may be about 3.8°, which is calculated by Equation 3, i.e., tan⁻¹{(10−5)/75}. In the given conditions, the ascending angle θ1 may be greater than 3.8° in case that the length D2 of the inner region 10in is less than 75 mm, while the ascending angle θ1 may be less than 3.8° in case that a length D1 of the outer region 10out is less than 75 mm. That is, the ascending angle θ1 may decrease with an increase in the length D2 of the inner region 10in.

The droplet nozzle 40 may reciprocate between the left edge position 10ea and the central position 10c of the substrate 10 at least one time. For example, the droplet nozzle 40 may move from the left edge position 10ea to the central position 10c along the horizontal path H and the ascending path A, and then may return back to the left edge position 10ea from the central position 10c along the ascending path A and the horizontal path H.

Referring to FIG. 3C, the surface 10s of the substrate 10 rotating about the central position 10c thereof may receive the droplets 2 from the droplet nozzle 40 gradually moving toward the surface 10s of the substrate 10.

For example, the droplet nozzle 40 may move along a descending path D gradually getting toward the surface 10s of the substrate 10 while approaching toward the central position 10c from the left edge position 10ea of the substrate 10. The droplet nozzle 40 may be spaced apart from the left edge position 10ea by the second gap G2 and spaced apart from the central position by the first gap G1. This embodiment may be adapted to treat the substrate 10 in which there is an increased risk of damages to patterns formed on the edge position 10ea or an area adjacent thereto than the central position 10c or an area adjacent thereto.

The droplet nozzle 40 may reciprocate between the left edge position 10ea and the central position 10c of the substrate 10 at least one time. For example, the droplet nozzle 40 may move from the left edge position 10ea to the central position 10c along the descending path D, and then may return back to the left edge position 10ea from the central position 10c along the descending path D.

Referring to FIG. 3D, the surface 10s of the substrate 10 rotating about the central position 10c thereof may receive the droplets 42 from the droplet nozzle 40 gradually moving toward the surface 10s of the substrate 10 after horizontally moving without the variation of gap between the droplet nozzle 40 and the surface 10s of the substrate 10.

For example, the droplet nozzle 40 may move along the horizontal path H in the outer region 10out between the left edge position 10ea and the dividing position 10da, and move along the descending path D in the inner region 10in between the dividing position 10da and the central position 10c.

The droplet nozzle 40 may be spaced apart from the surface 10s of the substrate 10 by the second gap G2 in the outer region 10out. The droplet nozzle 40 may gradually descend while moving toward the central position 10c from the dividing position 10da in the inner region 10in. Therefore, the droplet nozzle 40 may be spaced apart from the central position 10c by the first gap G1. A descending angle θ2 may be given by a principle substantially identical to that of obtaining the ascending angle θ1 formerly described with reference to FIG. 3C.

The droplet nozzle 40 may reciprocate between the left edge position 10ea and the central position 10c of the substrate 10 at least one time. For example, the droplet nozzle 40 may move from the left edge position 10ea to the central position 10c along the horizontal path H and the descending path D, and then may return back to the left edge position 10ea from the central position 10c along the descending path D and the horizontal path H.

Referring to FIG. 3E, the droplet nozzle 40 may move from the left edge position 10ea to the central position 10c of the substrate 10 sequentially along the horizontal path H, the ascending path A, the descending path D, and the horizontal path H. For example, the droplet nozzle 40 may be spaced apart from the left edge position 10ea and the central position 10c by the first gap G1, and spaced apart from the diving position 10da by the second gap G2. This embodiment may be adapted to treat the substrate 10 in which there is an increased risk of damages to patterns formed on the diving position 10da or an area adjacent thereto.

The droplet nozzle 40 may reciprocate between the left edge position 10ea and the central position 10c of the substrate 10 at least one time. For example, the droplet nozzle 40 may move from the left edge position 10ea to the central position 10c sequentially along the horizontal path H, the ascending path A, the descending path D and the horizontal path H, and then may return back to the left edge position 10ea from the central position 10c sequentially along the horizontal path H, the descending path D, the ascending path A and the horizontal path H.

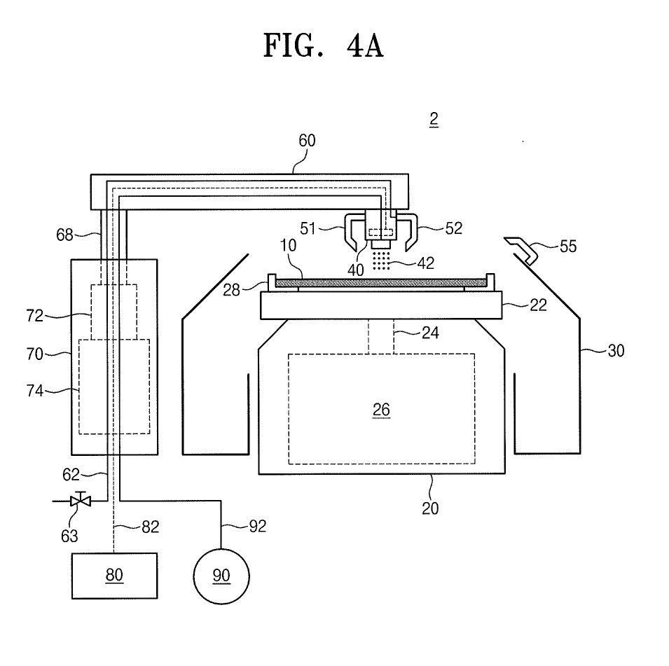

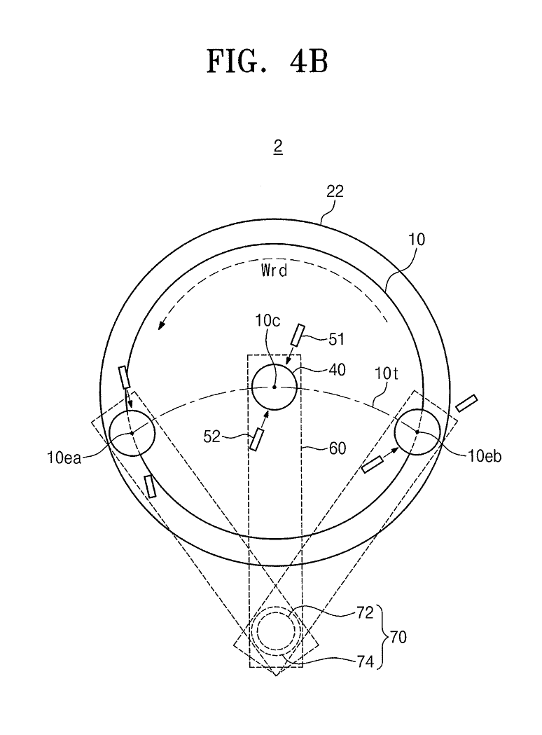

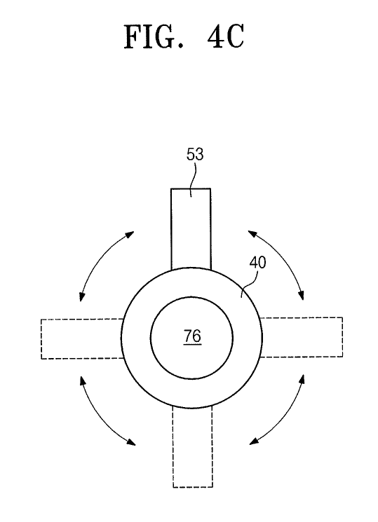

FIG. 4A illustrates a schematic view of an apparatus for treating a substrate according to another exemplary embodiment. FIG. 4B illustrates a plan view of a portion of FIG. 4A. FIG. 4C illustrates a plan view of a modified example of FIG. 4B.

Referring to FIGS. 4A and 4B, a substrate treatment apparatus 2 may be configured to have a structure substantially identical or similar to that of the substrate treatment apparatus 1 of FIG. 1A. Differently from the substrate treatment apparatus 1, the substrate treatment apparatus 2 may include twin side nozzles 51 and 52. For example, the twin side nozzles 51 and 52 may include a first side nozzle 51 provided on a first side of the droplet nozzle 40 and a second side nozzle 52 provided on a second side of the droplet nozzle 40. The first and second side nozzles 51 and 52 may be located symmetrically with respect to the droplet nozzle 40. Alternatively, the first and second side nozzles 51 and 52 may be provided on the nozzle arm 60.

The first and second side nozzles 51 and 52 may be respectively located upstream and downstream sides of the rotation direction Wrd of the substrate 10. For example, the pivotal rotation of the nozzle arm 60 may horizontally move the first and second side nozzles 51 and 52 along the locus 10t. While the droplet nozzle 40 moves between the left edge position 10ea and the central position 10c of the substrate 10, the first side nozzle 51 may spray the wetting liquid onto the substrate 10 in a direction oriented toward the droplet nozzle 40. The wetting liquid sprayed through the first side nozzle 51 may flow consistently with the rotation direction Wrd of the substrate 10 between the left edge position 10ea and the central position 10c of the substrate 10.

When the droplet nozzle 40 moves between the central position 10c and the right edge position 10eb of the substrate 10, the second side nozzle 52 may spray the wetting liquid onto the substrate 10 in a direction oriented toward the droplet nozzle 40. The wetting liquid sprayed through the second side nozzle 52 may flow consistently with the rotation direction Wrd of the substrate 10 between the central position 10c and the right edge position 10eb of the substrate 10.

The first and second side nozzles 51 and 52 may spray the wetting liquid, whose flow direction is consistent with the rotation direction Wrd of the substrate 10, even if the droplet nozzle 40 moves along the locus 10t between the left and right edge positions 10ea and 10eb. In other words, the twin side nozzles 51 and 52 may inject the wetting liquid onto the substrate 10 without interference between the flow direction of the wetting liquid and the rotation direction Wrd of the substrate 10. As such, the substrate treatment apparatus 2 may be adapted to treat the substrate 10 (e.g., cleaning treatment) in a full-scan mode.

Alternatively, as shown in FIG. 4C, the substrate treatment apparatus 2 may include a movable side nozzle 53 instead of the twin side nozzles 51 and 52. The movable side nozzle 53 may be configured to revolve around the droplet nozzle 40. The movable side nozzle 53 may be designed revolutionarily rotatable by receiving a driving force from a motor 76. The motor 76 may be provided inside or outside of the nozzle arm 60.

The motor 76 may drive the movable side nozzle 53 to revolve around the droplet nozzle 40. For example, the movable side nozzle 53 may revolve at an angle of about 360° or about 180° along at least one of leftward and rightward directions.

Since the movable side nozzle 53 can revolve around the droplet nozzle 40, it may serve as the twin side nozzles 51 and 52 of FIG. 4A. For example, when the droplet nozzle 40 equipped with the movable side nozzle 53 moves along the locus 10t between the left edge position 10ea and the central position 10c of the substrate 10, the movable side nozzle 53 may revolve to a position corresponding to that of the first side nozzle 51. When the droplet nozzle 40 moves along the locus 10t between the central position 10c and the right edge position 10eb of the substrate 10, the movable side nozzle 53 may revolve to a position corresponding to that of the second side nozzle 52.

As such, the substrate treatment apparatus 2 including the movable side nozzle 53 may be adapted to treat the substrate 10 (e.g., cleaning treatment) in both a full-scan mode and a half-scan mode.

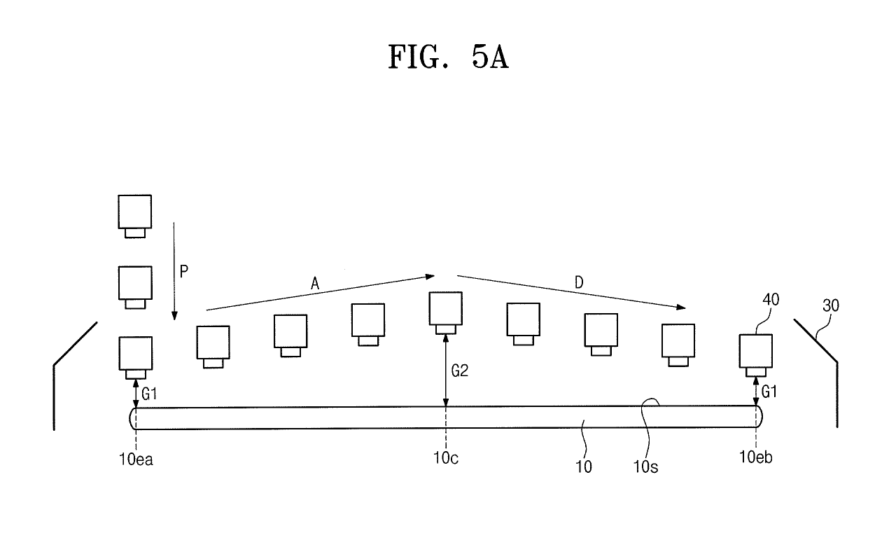

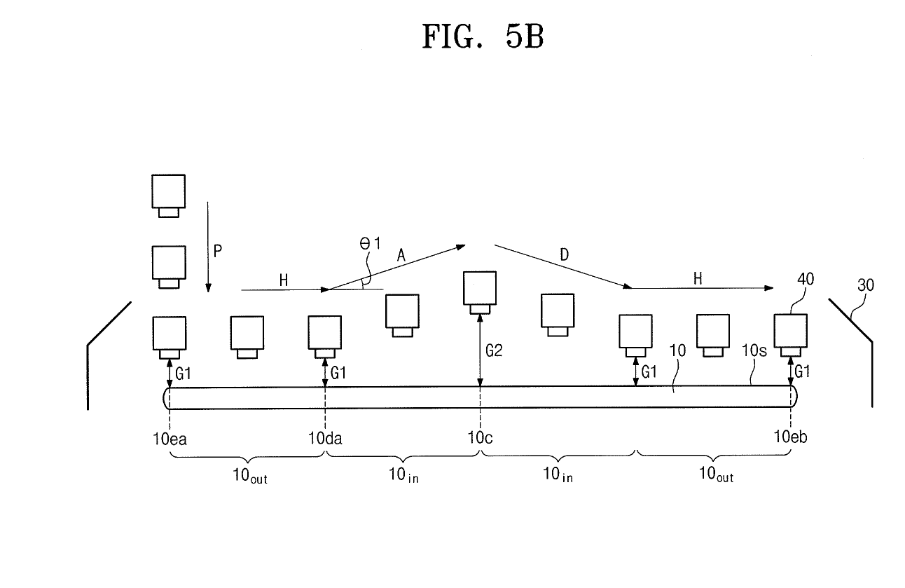

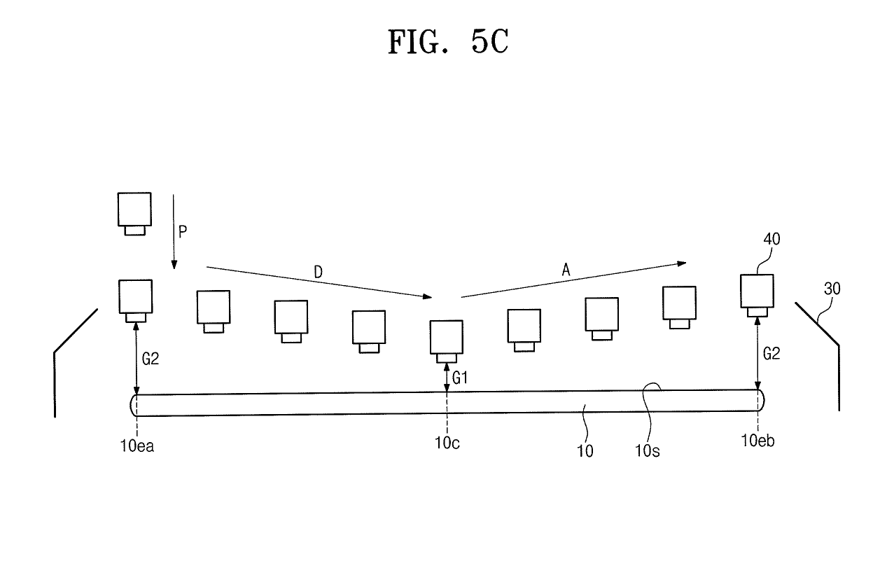

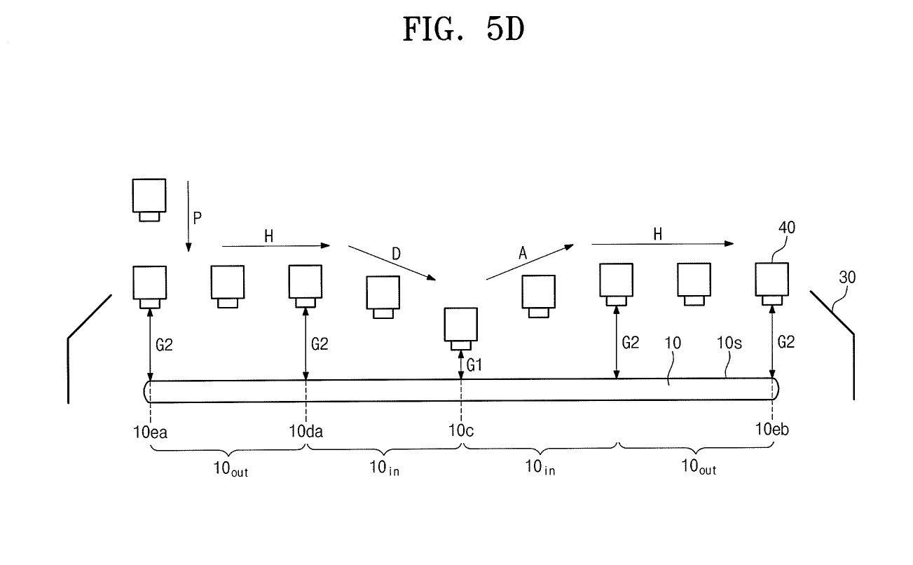

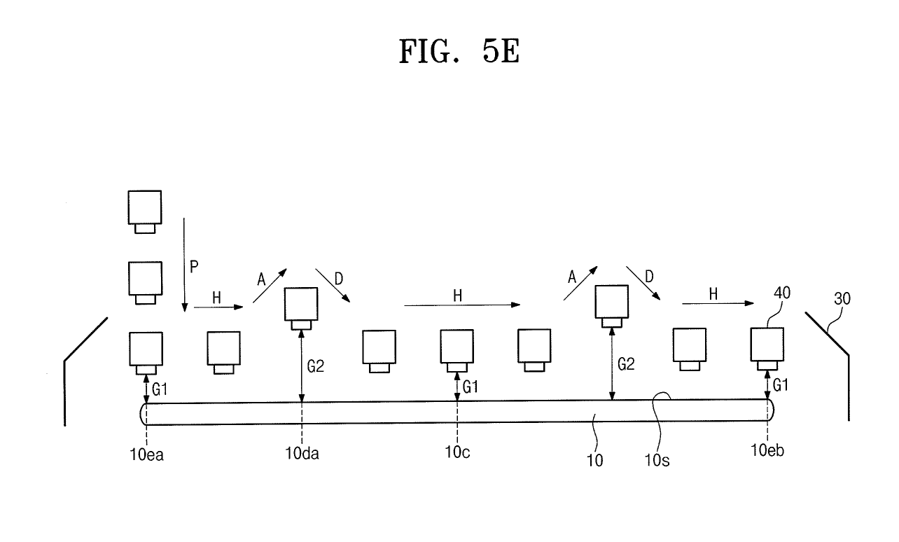

FIGS. 5A to 5E illustrate cross-sectional views of stages in a method for treating a substrate using the substrate treatment apparatus 2 of FIG. 4A.

Referring to FIG. 5A, the droplet nozzle 40 may spray the droplets 42 onto the surface 10s of the substrate 10 rotating around the central position 10c thereof while moving along the ascending path A and the descending path D.

For example, the droplet nozzle 40 may gradually move away from the surface 10s of the substrate 10 while moving toward the central position 10c from the left edge position 10ea of the substrate 10, and gradually move toward the surface 10s of the substrate 10 while moving toward the right edge position 10eb from the central position 10c of the substrate 10. The droplet nozzle 40 may be spaced apart from the left and right edge positions 10ea and 10eb by the first gap G1, and spaced apart from the central position 10c by the second gap G2.

The droplet nozzle 40 may reciprocate between the left edge position 10ea and the right edge position 10eb of the substrate 10 at least one time. For example, the droplet nozzle 40 may move from the left edge position 10ea to the right edge position 10eb along the ascending path A and the descending path D, and then may return back to the left edge position 10ea from the right edge position 10eb along the descending path D and the ascending path A.

Referring to FIG. 5B, the droplet nozzle 40 may spray the droplets 42 onto the surface 10s of the substrate 10 while moving toward the central position 10c from the left edge position 10ea along the horizontal path H and the ascending path A and moving toward the right edge position 10eb from the central position 10eb along the descending path D and the horizontal path H.

For example, from the left edge position 10ea to the central position 10c, the droplet nozzle 40 may move along the horizontal path H in the outer region 10out and move along the ascending path A in the inner region 10in. From the central position 10c to the right edge position 10eb, the droplet nozzle 40 may move along the descending path D in the inner region 10in and move along the horizontal path H in the outer region 10out.

In the outer region 10out, the droplet nozzle 40 may be spaced apart from the surface 10s of the substrate 10 by the first gap G1. In the inner region 10in, the droplet nozzle 40 may gradually move away from the surface 10s of the substrate 10 while moving toward the central position 10c. The droplet nozzle 40 may therefore be spaced apart from the central position 10c of the substrate 10 by the second gap G2. The ascending angle θ1 of the droplet nozzle 40 may be given by the same principle formerly described with reference to FIG. 3C.

The droplet nozzle 40 may reciprocate between the left edge position 10ea and the right edge position 10eb of the substrate 10 at least one time. For example, the droplet nozzle 40 may move from the left edge position 10ea to the right edge position 10eb sequentially along the horizontal path H, the ascending path A, the descending path D, and the horizontal path H, and then may return back to the left edge position 10ea from the right edge position 10eb sequentially along the horizontal path H, the descending path D, the ascending path A, and the horizontal path H.

Referring to FIG. 5C, the droplet nozzle 40 may spray the droplets 42 onto the surface 10s of the substrate 10 while moving along the descending path D and the ascending path A. For example, the droplet nozzle 40 may move from the left edge position 10ea to the central position 10c of the substrate 10 along the descending path D, and may move from the central position 10c to the right edge position 10eb of the substrate 10 along the ascending path A.

The droplet nozzle 40 may reciprocate between the left edge position 10ea and the right edge position 10eb of the substrate 10 at least one time. For example, the droplet nozzle 40 may move from the left edge position 10ea to the right edge position 10eb along the descending path D and the ascending path A, and then may return back to the left edge position 10ea from the right edge position 10eb along the ascending path A and the descending path D.

The droplet nozzle 40 may be respectively spaced apart from the left and right edge positions 10ea and 10eb by the second gap G2, and spaced apart from the central position 10c by the first gap G1.

Referring to FIG. 5D, the droplet nozzle 40 may move along the horizontal path

H and the descending path D between the left edge position 10ea and the central edge position 10c of the substrate 10, and move along the ascending path A and the horizontal path H between the central position 10c and the right edge position 10eb of the substrate 10.

For example, in the outer region 10out, the droplet nozzle 40 may be spaced apart from the surface 10s of the substrate 10 by the second gap G2. In the inner region 10in, the droplet nozzle 40 may gradually move toward the surface 10s of the substrate 10 while moving toward the central position 10c. The droplet nozzle 40 may therefore be spaced apart from the central position 10c of the substrate 10 by the first gap G1.

The droplet nozzle 40 may reciprocate between the left edge position 10ea and the right edge position 10eb of the substrate 10 at least one time. For example, the droplet nozzle 40 may move from the left edge position 10ea to the right edge position 10eb sequentially along the horizontal path H, the descending path D, the ascending path A, and the horizontal path H, and then may return back to the left edge position 10ea from the right edge position 10eb sequentially along the horizontal path H, the ascending path A, the descending path D, and the horizontal path H.

Referring to FIG. 5E, the droplet nozzle 40 may move from the left edge position 10ea to the right edge position 10eb repeatedly along the horizontal path H, the ascending path A, and the descending path D. The droplet nozzle 40 may be respectively spaced apart from the left edge position 10ea, the right edge position 10eb, and the central position 10c by the first gap G1, and spaced apart from the dividing position 10da by the second gap G2.

The droplet nozzle 40 may reciprocate between the left edge position 10ea and the right edge position 10eb of the substrate 10 at least one time. For example, the droplet nozzle 40 may move from the left edge position 10ea to the right edge position 10eb repeatedly along the horizontal path H, the ascending path A, and the descending path D, and then may return back to the left edge position 10ea from the right edge position 10eb repeatedly along the horizontal path H, the descending path D, and the ascending path A.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. An apparatus for treating a substrate, the apparatus comprising:
a spin chuck supporting a substrate;
a nozzle movably disposed on the spin chuck, the nozzle providing droplets of a treatment liquid onto a surface of the substrate; and
a nozzle arm moving the nozzle above the spin chuck,
wherein the nozzle arm moves the nozzle horizontally along the surface of the substrate, and vertically with respect to the surface of the substrate,
wherein the nozzle arm moves the nozzle between an edge of the substrate and a center of the substrate, the nozzle moving away from the surface of the substrate while approaching toward the center of the substrate, and
wherein droplets provided onto the center of the substrate have a smaller vertical spacing than that of droplets provided onto the edge of the substrate.

2. The apparatus as claimed in claim 1, wherein the nozzle is spaced apart from the edge of the substrate by a first gap, and spaced apart from the center of the substrate by a second gap greater than the first gap.

3. The apparatus as claimed in claim 1, wherein the nozzle continuously or stepwisely moves way from the surface of the substrate, while moving toward the center of the substrate from the edge of the substrate.

4. The apparatus as claimed in claim 3, wherein the nozzle gradually moves away from the substrate while moving toward the center of the substrate from a side edge of the substrate, and gradually descends toward the substrate while returning toward the side edge of the substrate from the center of the substrate, the side edge of the substrate intersecting a traveling path of the nozzle.

5. The apparatus as claimed in claim 3, wherein the nozzle gradually moves away from the substrate while moving toward the center of the substrate from one of opposing lateral edges of the substrate, and gradually descends toward the substrate while returning toward another of the opposing lateral edges of the substrate from the center of the substrate, the opposing lateral edges of the substrate intersect a traveling path of the nozzle.

6. The apparatus as claimed in claim 3, wherein:
the nozzle is spaced apart from the edge of the substrate by a first gap and spaced apart from the center of the substrate by a second gap greater than the first gap, and
a ratio of the first gap to the second gap is about 1:2.

7. The apparatus as claimed in claim 1, wherein:
the substrate includes a boundary that divides a radius thereof,
the nozzle moves along a horizontal path that passes across an outer region between the edge and the boundary of the substrate and along an ascending path that passes across an inner region between the boundary and the center of the substrate, and
the horizontal path has substantially no variation of gap between the nozzle and the surface of the substrate, and the ascending path gradually moves away from the surface of the substrate while approaching the center of the substrate.

8. The apparatus as claimed in claim 7, wherein:
the nozzle reciprocates between the edge and the center of the substrate at least one time,
the nozzle horizontally moves between the edge and the boundary of the substrate without a variation of gap between the nozzle and the surface of the substrate,
the nozzle moves from the boundary of the substrate to the center of the substrate while gradually ascending away from the surface of the substrate while approaching the center of the substrate, and
the nozzle moves from the center of the substrate to the boundary of the substrate while gradually descending toward the surface of the substrate while approaching the boundary of the substrate.

9. The apparatus as claimed in claim 7, wherein:
the nozzle reciprocates between opposing lateral edges of the substrate across the center of the substrate at least one time, the opposing lateral edges of the substrate intersecting a traveling path of the nozzle,
the nozzle horizontally moves between each of the opposing lateral edges and the boundary of the substrate without a variation of gap between the nozzle and the surface of the substrate,
the nozzle moves from the boundary of the substrate to the center of the substrate while gradually ascending away from the surface of the substrate while approaching the center of the substrate, and
the nozzle moves from the center of the substrate to the boundary of the substrate while gradually descending toward the surface of the substrate while approaching the boundary of the substrate.

10. The apparatus as claimed in claim 7, wherein:
the nozzle is respectively spaced apart from the edge and boundary of the substrate by a first gap,
the nozzle is spaced apart from the center of the substrate by a second gap greater than the first gap, and
a ratio of the first gap to the second gap is about 1:2.

11-19. (canceled)

20. An apparatus for treating a substrate, comprising:
a nozzle arm moving a nozzle along a surface of a substrate, and changing a gap between the nozzle and the surface of the substrate, the substrate being held by a spin chuck,
wherein the nozzle provides droplets of a treatment liquid onto the surface of the substrate, the substrate rotating on the spin chuck, and
wherein the droplets provided onto a center of the substrate have a first vertical spacing different from a second vertical spacing of droplets provided onto the edge of the substrate.

21. The apparatus as claimed in claim 20, wherein:
the nozzle is spaced apart from the edge of the substrate by a first gap and spaced apart from the center of the substrate by a second gap greater than the first gap, the second gap being smaller than twice the first gap, and
the second vertical spacing of the droplets provided from the nozzle spaced apart from the center of the substrate by the second gap is smaller than the first vertical spacing of the droplets provided from the nozzle spaced apart from the edge of the substrate by the first gap.

22. The apparatus as claimed in claim 21, wherein a ratio of the first gap to the second gap is about 1:2.

23-26. (canceled)

27. The apparatus as claimed in claim 20, wherein:
the droplets having the first vertical spacing are injected through the nozzle spaced apart from the edge of the substrate by the first gap, and the droplets having the second vertical spacing are injected through the nozzle spaced apart from the center of the substrate by the second gap,
a ratio of the first gap to the second gap is about 1:2, and
the nozzle sprays droplets with an injection quantity per unit time that is substantially constant.

28. The apparatus as claimed in claim 20, wherein:
the nozzle is spaced apart from the edge of the substrate by a first gap and spaced apart from the center of the substrate by a second gap smaller than the first gap,
the second vertical spacing of the droplets provided from the nozzle spaced apart from the center of the substrate by the second gap is greater than the first vertical spacing of the droplets provided from the nozzle spaced apart from the edge of the substrate by the first gap, and
a ratio of the second gap to the first gap is about 1:2.

29-43. (canceled)

44. An apparatus for treating a substrate, the apparatus comprising:
a spin chuck supporting a substrate;
a movable nozzle above the spin chuck, the nozzle providing droplets of a treatment liquid onto a surface of the substrate; and
a nozzle arm attached to the nozzle and moving the nozzle between an edge of the substrate and a center of the substrate, droplets of the treatment liquid provided onto the center of the substrate having a smaller vertical spacing than that of droplets provided onto the edge of the substrate.

45. The apparatus as claimed in claim 44, wherein the nozzle arm moves the nozzle between the edge of the substrate and the center of the substrate along the surface of the substrate, while varying a vertical distance between the nozzle and the surface of the substrate.

46. The apparatus as claimed in claim 45, wherein the vertical distance between the nozzle and the surface of the substrate increases as a horizontal distance between the nozzle and the center of the substrate decreases.

47. The apparatus as claimed in claim 46, wherein a ratio between a minimum vertical distance and a maximum vertical distance is about 1:2.

48. The apparatus as claimed in claim 47, wherein the minimum vertical distance is at the edge of the substrate, and the maximum vertical distance is at the center of the substrate.
